(19) United States
(12) Patent Application Publication
(10) Pub. No.: US 2005/0082520 A1
(43) Pub. Date: Apr. 21, 2005

(54) Monolithic two color quantum-well photodetector

(76) Inventors: Ayub M. Fathimulla, Ellicott City, MD (US); Harry Stephen Hier, Sykesville, MD (US); Olaleye A. Aina, Columbia, MD (US)

Correspondence Address: Hung Chang Lin, 8 Schindler Ct., Silver Spring, MD, 20903, US

(21) Appl. No.: 10/678,801

(22) Filed: Oct. 6, 2003

(51) Int. Cl. H01L 29/06

(52) U.S. Cl. 257/14

(57) ABSTRACT

An integrated dual wavelength quantum-well infrared photodetector has two absorption peaks of photo response. The structure has a standard quantum well to yield a peak photo response at one wavelength and a sub-well to yield a peak photo response at a second wavelength. The standard quantum well and the sub-well is separated by a barrier. The barrier-well-subwell-well barrier layers are structured periodically. Additional quantum wells and sub-wells may be added to yield a multi-wavelength infrared photodetector.

### BACKGROUND OF THE INVENTION

(1) Field of the Invention

This invention relates to photodetectors, particularly to quantum-well integrated photodectors (QWIP) for detecting more than one color.

(2) Brief Description of Related Art

There are many applications for multi-wavelength photodetectors that are simultaneously responsive to two different wavelengths. These applications include missile seekers, infrared cameras for surveillance, target recognition, and environmental monitoring. These wavelengths can be in one of three ranges: near infared (NIR), mid-wavelength infrared (MW), and long-wavelength infrared (LW), Depending on the application, the wavelength pairs required can be NIR-MW, MW-MW, MW-LW, or LW-LW. Implementation of these systems using discrete detectors becomes expensive, bulky and it can result in inferior performances that do not satisfy the system requirements. Monolithically integrated detectors will not only simplify the signal processing aspect of the system but also results in critical performance enhancements. Significant flexibility and performance improvements can be achieved by adding more detectors to cover a broader wavelength.

Multi-wavelength detectors require integration of detectors with different vertical physical dimensions and different responsivities within their individual spectral bands. There are two approaches of monolithically integrating two detector materials on a single substrate. First, is the widely used vertical integration, in which the material for the two wavelengths are grown vertically in one growth sequence, with a thin etch stop layer grown between each QWIP structure. This approaches yield the best material properties because both device layers are grown together without growth interruptions. The typical thickness of the standard QWIP material structures that are commonly used m and thickness of the vertically integrated dual wavelength μ are about 2.0 m. Fabrication of QWIP based focal plane arrays structure is greater than 4.0 require etching of mesas through these structures to isolate each of the tens of thousands of pixels in a typical array. While the thickness of the single wavelength structures is manageable for device processing, the multi-wavelength structures are virtually impossible to fabricate because of the excessively tall mesas. The tall mesas will result in lower device fabrication yields. Additionally, the wafer growth cost is increased because of the prolonged growth duration. Further, the non planarity of the structures will make fabrication of four different gratings for coupling the radiation difficult.

The drawback of the fabrication process complexity for the vertical integration of two-color QWIPs can be alleviated by lateral integration. The integration of two colors (MWIR and LWIR) by selective epitaxy of MW and LW structures on InP substrate yields manageable total thickness of the layers for device processing, but requires two growth sequences as disclosed in U.S. Pat. No. 6,407,439 B1 However, both approaches are limited to integration of two QWIP structures having response in MW-MW or LW-LW or MW-LW region. As a result of this serious problem, in this invention a thinner layer structure designs is proposed that will be easier to fabricate. The approach includes using novel quantum well material combinations to achieve two wavelength windows using thicknesses that are comparable to those of single wavelength designs.

### SUMMARY OF THE INVENTION

An object of this invention is to integrate vertically a quantum-well photodetector using thinner layer structure which is easier to fabricate. A second object of this invention is to achieve two wavelength windows using thicknesses that are comparable to those of single wavelength designs.

These objects are achieved by bandgap engineering in a single structure to extend the design of standard QWIPs to one that contains a period with two different types of quantum wells, i.e. a multi-wavelength structure. Secondly, the new QWIP structure contains a'sequence of barrier-well-subwell-well-barrier layers.

### BRIEF DESCRIPTION OF THE DRAWINGS

FIG. 1a shows a standard GaInAs quantum well structure with AlInAs barriers; FIG. 1b shows calculated response of QWIP with a standaard GaInAs/AlInAs well having a peak response at 4.7 μm wavelength.

FIG. 2a shows GaInAs quantum well structure with InAs sub-well. Total thickness of the well 46 Å, sub-well thickness 24 Å; FIG. 2b shows calculated response of QWIP with modified GaInAs well containing a InAs sub-well. The response is shifted from 4.7 to 4.2-μm wavelength.

FIG. 3a shows a layer structure of a single period for a 4-μm/5-μm dual-wavelength quantum well infrared photodetector that uses InAs sub-wells; FIG. 3b shows calculated response of a GaInAs/AlInAs dual-wavelength (4.0-μm & 5.0-μm) QWIP structure that uses InAs sub-wells.

FIG. 4 shows the effect of adding standard wells to two wells having InAs sub-well. The response (a) and (b) are at 4.2 and 4.7 μm respectively.

FIG. 5 shows the effect of thickness variation of the sub-well on wavelength of dual absorption detector; (a) wavelength constant at 4.87 μm and (b) wavelength varies 3.5 to 4.0 μm. The total thickness of the well is kept at 3.6 nm

FIG. 6 shows wavelength for the absorption peak versus well width for a GaAs/AlGaAs QWIP structure a) without InAs sub-well, and b) with an InAs sub-well.

FIG. 7a shows a typical GaAs based material structure of the combined MW-LW detector; FIG. 7b shows spectral response of the dual absorption QWIP sturcture based on GaAs/AlGaAs material system.

FIG. 8 shows calculated response of: a) GaAIGaAs QWIP that uses InAs sub-wells to enhance the line width of the absorption, and b) standard intraband transition for GaAs quantum well.

FIG. 9a shows a typical material structure of the dual LW-IR wavelength QWIP; FIG. 9b shows calculated response of GaInAs/AlGalnAs dual-wavelength (8-μm and 12-μm) QWIP structure InAs sub-wells.

FIG. 10 shows FTIR spectra of multi-wavelength QWIP material structures.

FIG. 11a shows mixed well design to minimize the dark current with AlGaAs barrier, Ga_{0.7}In_{0.3} As well, GaAs mini-well; FIG. 11b shows spectral response of the mixed well structure in minimize the dark current.

FIG. 12 shows structure of MW-QWIP designed to reduce the leakage currents.

### DETAILED DESCRIPTION OF THE INVENTION

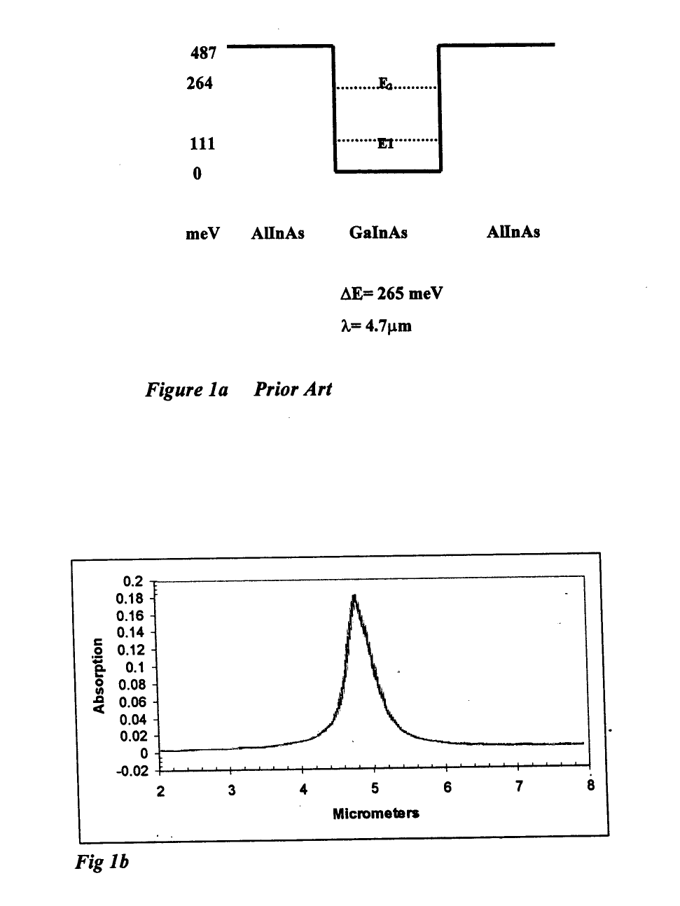

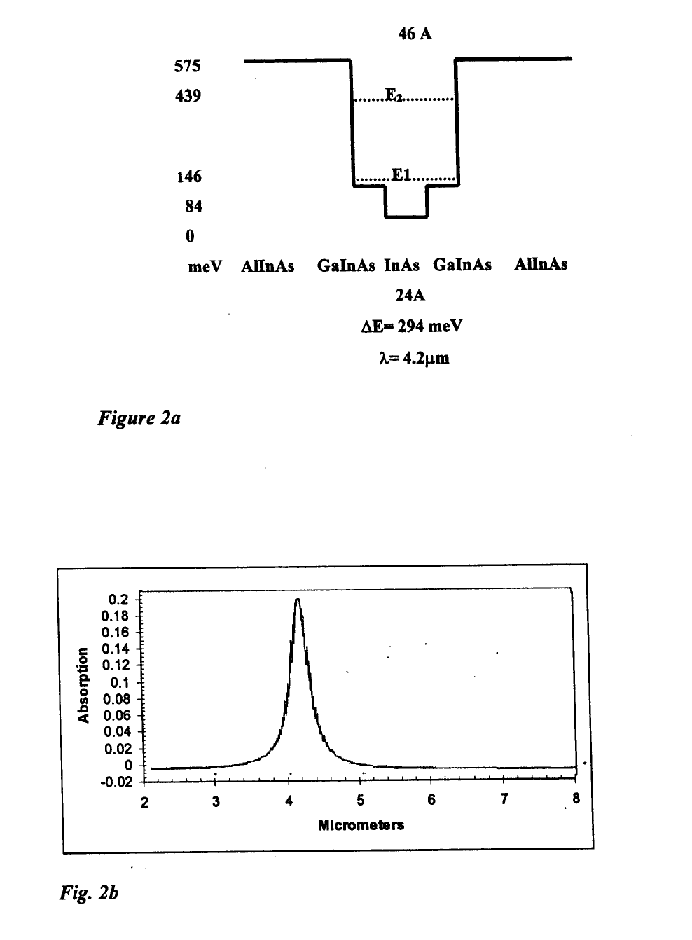

FIGS. 1a and 1b show the energy levels and calculated photoresponse of a single well of a standard barrier-well-barrier type QWIP. The present invention contains a sequence of barrier-well-subwell-well-barier layers as shown in FIG. 2a.

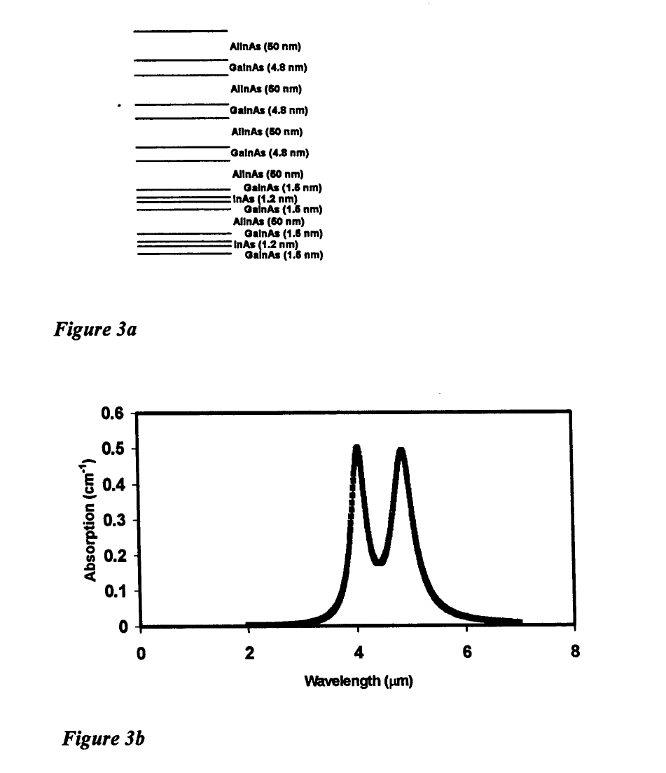

One such design and the photoresponse are illustrated in FIGS. 2a and 2b. The addition of the sub-well reduces the lowest wavelength possible for the material system and structure chosen, compared to the device without the sub-well level. In some instances, the design can place the lowest energy level of the quantum well in the sub-well. This energy level is pinned to that position and this allows the independent adjustment of the upper level of the transition. For the examples shown in FIGS. 1a, 1b, 2a and 2b, the standard QWIP with GaInAs well absorbs light at a wavelength of 4.7 μm, and the GaInAs well that contains the InAs sub-well absorbs light at a wavelength of 4.2 μm. Therefore combining any two QWIP material structures with and without sub-well can be made to have dual wavelength response in MWIR-to-VLWIR range. For example 4 μm-5 μm wavelength dual absorption QWIPs can be designed (shown in FIGS. 3a, 3b) using Ga_{0.47}In_{0.53}As as the well material (with and without an InAs sub-well) and Al_{0.48}ln_{0.52}As as the barrier material. Therefore the novel structure which is simultaneously responsive to two wavelengths simplifies the integration of multiple wavelength detectors on a single substrate. Alternately InAs quantum dots of different periods also can be used to design multi-wavelength QWIPs.

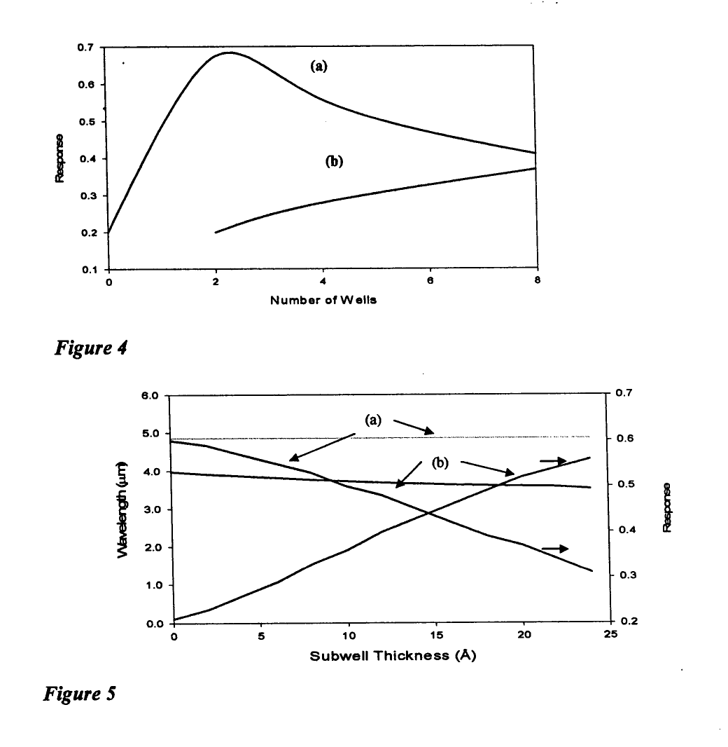

Simulations were performed extensively to investigate the effect of the material system, location, number, and thickness of the sub-well response of the novel detector structure. First, the number of standard wells was varied while keeping number of the sub-well to two and total number of wells constant (20). FIG. 4 shows the response of the detector, and the absorption with only sub-wells occurs at wavelength of 4.2 μm. With addition of standard wells the spectra shows dual absorption (4.2 and 4.7 μm) and the response becomes equal for structure having eight standard and two sub-wells. In the second simulation, the thickness of the sub-wells was varied keeping the total thickness of the wells constant. FIG. 5 shows the effect on the wavelength and response with variation of the thickness of the sub-well. In the simulation the total thickness of the well is kept constant at 3.6 nm. The first wavelength remains constant (4.87 μm) and the second wavelength varies from 3.5 to 4.0 μm. Also in the figure the response is asymmetrical and becomes equal for a sub-well thickness of 1.4 nm.

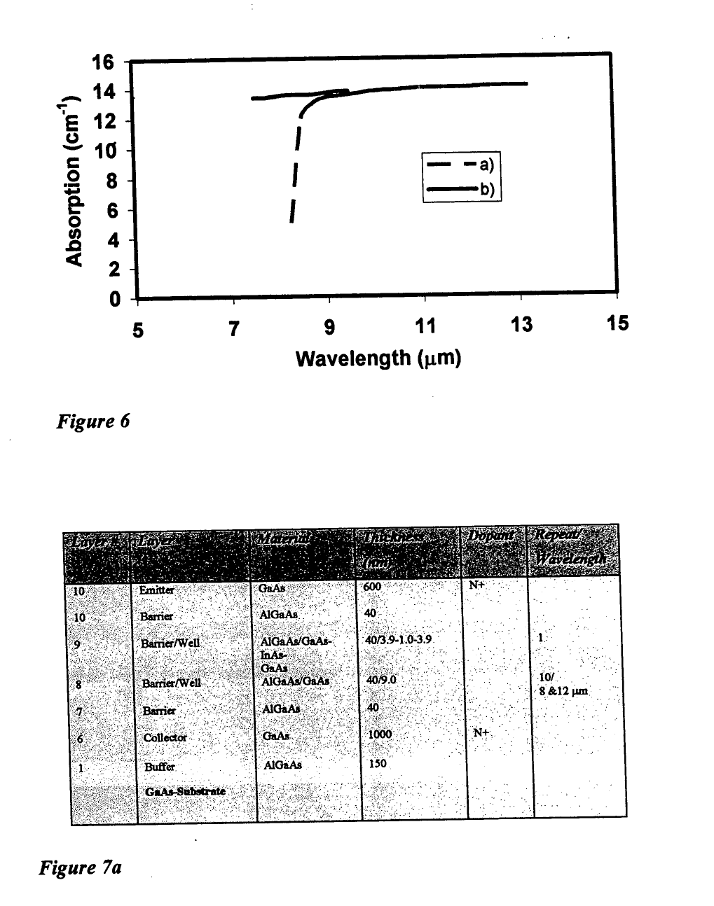

The third example of the simulation of the QWIP is changing the material structure to GaAs/AlGaAs. FIG. 6 shows the calculated spectral response of a GaAs-well/InAs-sub-well/AlGaAs-barrier quantum-well detector system. The absorption by the simple GaAs/AlGaAs quantum-well system drops rapidly near 9.0 μm; however, the design that includes an InAs sub-well maintains the absorption strength well to 7.5 μm.

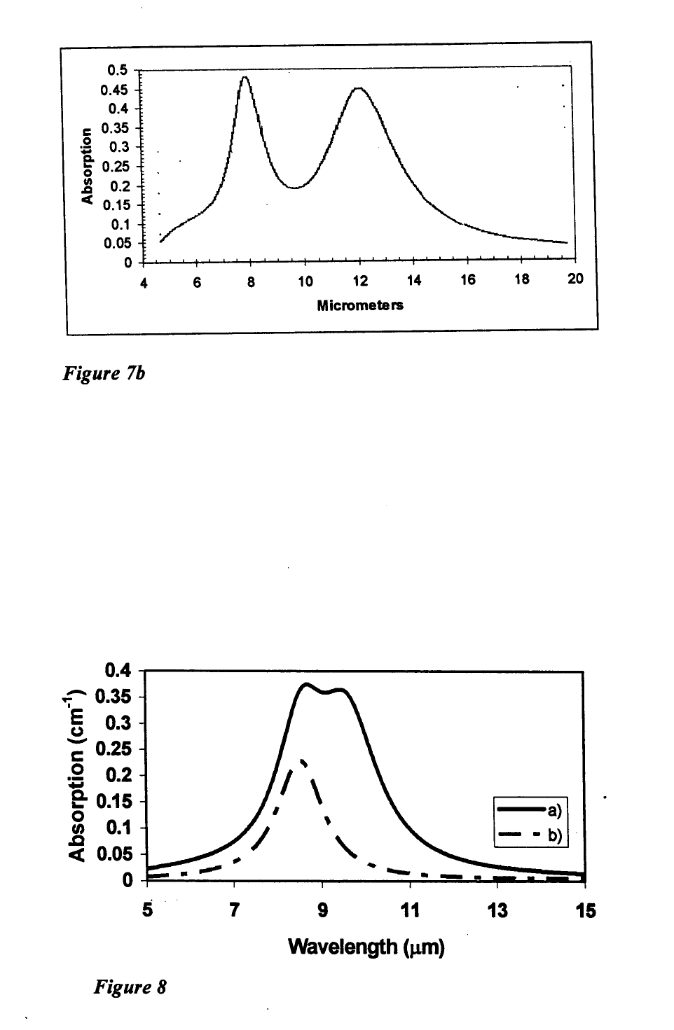

Further, simulations were performed by varying the number, and thickness of sub-wells, and the ratio of sub-wells to standard wells. For example, the structure shown in FIGS. 7a, 7b was optimized for equal response at 8.0 and 12.0 μm using GaAs/Al_{0.3} Ga_{0.7}As material system. Therefore the approach of adding sub-wells can be applied not only to any material system but also the QWIPs can be designed to have response in any given wavelength. The following few examples illustrate the novelty of the proposed design of the QWIPs.

An alternative to a two-wavelength detector is one that has a wider spectral response peak. FIG. 8 shows that the two-color detector can be optimized to give a wide spectral response by varying the thickness of the sub-well. Note that the absorption is also enhanced in this structure due to the inclusion of the sub-well. Changing the sub-well thickness, number of sub-wells, and location of the sub-wells can further increase the spectral width.

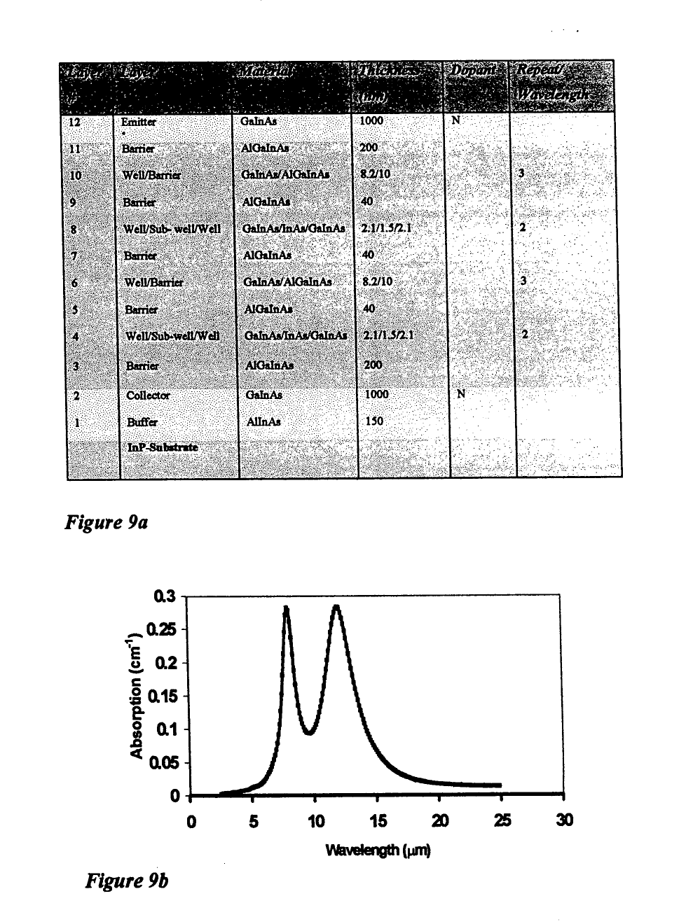

A second example of a typical QWIP material structure for a 8-μm/12-μm dual wavelengths uses GaInAs as well material (with and without sub-well) and AlGalnAs as the barrier material. Each set of two wells and barriers are optimized to give the required two-color operation. The addition of the sub-well reduces the lowest wavelength possible for the material system and structure chosen, compared to the structure without the sub-well. The structure can be designed to place the lowest energy level of the quantum well in the sub-well. Since the energy level is pinned to that position; this allows the independent adjustment of the upper level of the transition by changing the well width. FIGS. 9a, 9b show the material structure and spectra of the QWIP designed to have absorption at 8 and 12 μm. In the figure, layers 3-12 form one period and can be repeated to increase the response. This simulation clearly demonstrates the ability to detect two wavelengths (8.0 and 12.0 μm) in a single wavelength region using lattice compatible materials and structures.

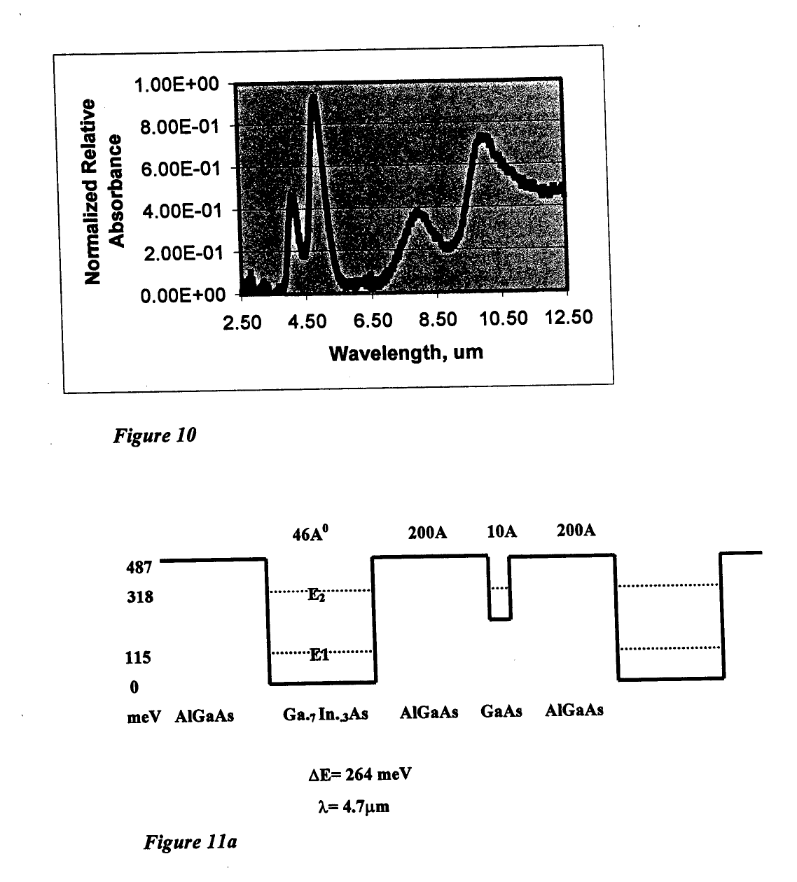

The final structure investigated was the integration of two such dual-color QWIPs shown in figures in 3a, 3b, 9a and 9b. The simulated spectral response of the integrated gave four absorption peaks at 4.0, 5.0, 8.0, and 12.5 μm wavelength. The material system contains AlinAs and AlGaInAs as barriers, a GaInAs well and an InAs sub-well. In order to evaluate the spectral response of novel designs of the multi-wavelength detectors, a vertically integrated TWO-dual wave length structures (mid-wave/mid-wave and long-wave/long-wave) was grown on InP substrate. FIG. 10 clearly shows Fourier Transform Infra Red (FTIR) spectra of four-wavelength QWIP material structures: two each at mid-wave (4.116 and 4.903 μm) and long-wave (8.094 and 10.12 μm) respectively. This demonstrates that dual wavelength detector can be developed using a single growth run with total thickness equal to that of a standard single wavelength detector. In addition, it is shown that four wavelength detector can be fabricated using either vertical or lateral (by selective epitaxy) integration of two-dual wavelength structures. The advantage of the selective epitaxy is the planar surface and easy to fabricate gratings of different pitches for coupling of light.

In a standard QWIP, the barrier is undoped and the well is doped. The doped well layers can be n or p-type. The doping can be uniform or delta/spike/planar doped. The spike doping can be Si, Sn, Te and Be, C for n and p-type QWIPs. Alternately, the barrier layers can be delta/spike/planar doped and provides donor or acceptor supply layer for the carriers in the well (undoped) of the QWIP. The spike doping or delta or planar doping provides two-dimensional electron or hole gas in the well and increases the mobility, which improves the performance of the QWIP. The sub-well can be narrow bandgap semiconductor or its quantum dots (e.g. InAs quantum dot in GaInAs well). Typical thicknesses of the well and the subwell are 2.0-10 mn and 0.5-3.0 nm respectively.

The combination of barrier/well materials in the QWIP structure can be extended to other semiconductor. The combination of the barrier/well can be: GaAs/AlGaAs, GaAs/GaInP, GaAs/AlAs, GaInAs/AlGaAs (AlAs, GaInP); GaInAs/AlInAs, GaInAs/AlGaAsSb, GaInAs/AlAsSb, GaAsSb/AlGaAsSb, GaInAs/AfnAsSb (InP), InP/AlInAs (AlGaAsSb, AlAsSb, AlGaAsSb, AInAsSb), InAs/AlGaAsSb(AlSb, AlAsSb, AlGaSb), InAs/AlGaInSb, InSb/AlInSb, GaN/AlGaN, GaInN/AlGaN, etc. and any other combination (including Thallium compounds) of binary, ternary, quadranary III-V semiconductor. QWIP can be extended to IV-IV semiconductor (Si, Ge, Sn, C), II-VI semiconductors (ZnSe, ZnS, CdTe, CdS, etc) or combinations of Ill-V and IV-IV (e.g. GaP/Si) or IV-IV and II-VI (e.g. ZnS/Si or III-V and II-VI (e.g. ZnSe/GaAs). The sub-well can be narrow bandgap semiconductor such as InAs, InSb, TlAs, TlP, TlSb, Ge, GeSn, etc. The substrate can be Si, GaAs, GaN, SiC, InP or other substrates on which the QWIP heterostructure is transferred by bonding/lift-off/growth. The QWIP structure can be can be grown via the group consisting of MBE/CBE/MEE/GSMBE/VPE/OMVPE/UHVCVD etc.

Leakage Current Reduction:

In the second embodiment of the invention is to implement a novel device structure to reduce leakage currents in the quantum well infrared photo-detectors (QWIPs). The standard QWIPs suffer from high leakage currents and poor leakage current uniformity, which results in degradation of the response. For wavelengths greater than 8.0 μm, the leakage current is worst because of smaller conduction band discontinuity for both GaAs and InP based devices. The leakage currents in QWIPs can be divided into two types: 1) process induced and 2) dark current. Careful processing of the devices can minimize the process induced leakage current and the uniformity. The origin of dark current in the QWIPs is due to: 1) phonon excitation, 2) thermionic and 3) defect-assisted tunneling. The dark currents due to the last two mechanisms can be minimized by proper design of the quantum well structure. Lower dark current enable background limited infrared photodetector (BLIP) operation at higher temperatures. Overall the leakage currents are detrimental to the detectivity of the detector. Various techniques have been proposed to reduce the leakage currents such as inserting a blocking layer in GaAs/AlGaAs QWIPs, (C. S. Wu et al., IEEE Tran. ED, Vol. 39, p. 234, 1992). In this structure, a thicker barrier of similar conduction band discontinuity was used, which is not sufficient to reduce leakage at higher temperatures (>40 K). In this invention, three approaches are proposed to reduce the leakage current in the QWIPs. First, is to add in the collector of the QWIP, an additional barrier of AlAs (AlSb, and AlAsSb) having large conduction band discontinuity and thickness of 2-5 nm to reduce the dark current. In this design, the lower energy electrons do not overcome the large conduction band discontinuity. The advantage of this approach is that, it requires one extra barrier and easy to implement.

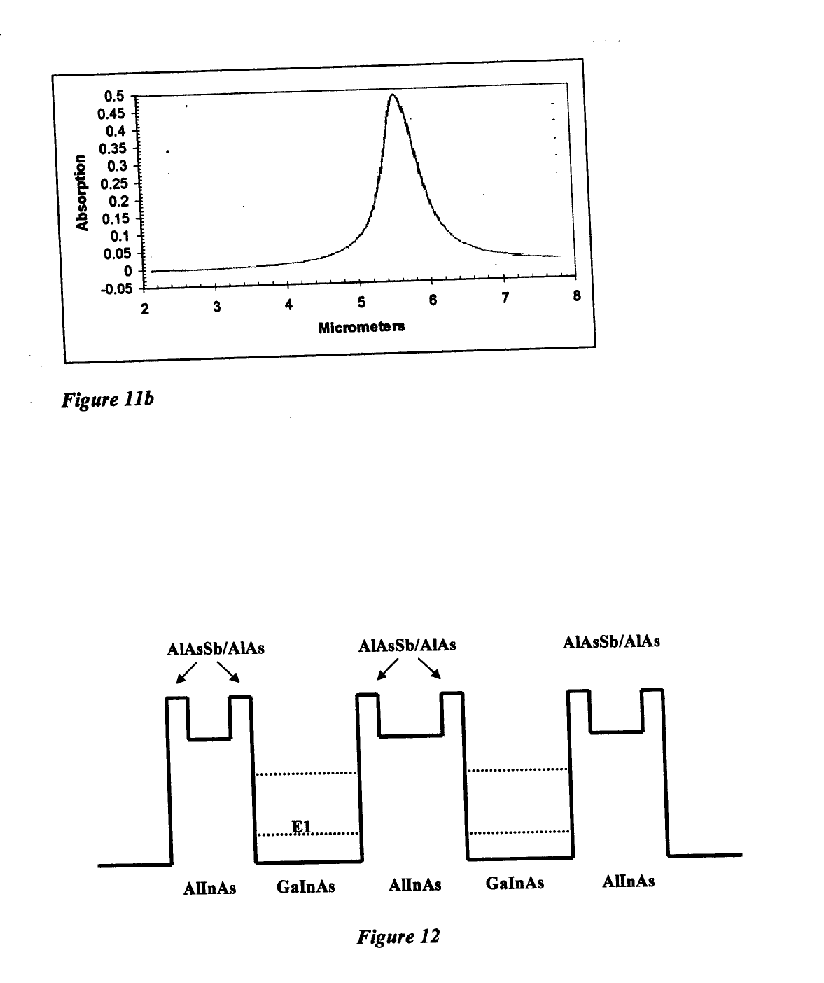

The second approach is to add a mini-well in the barrier of the QWIP, which enables electrons to tunnel through the barriers. The mini-level is designed to have a single state that is resonant with the upper state of the GaInAs well. This design shown in the FIG. 11 minimizes the tunneling of electrons through the defects in the barriers.

The third approach is to use step barriers as shown in the FIG. 12. This structure is complicated to grow. The three approaches proposed in this invention can be applied to QWIPs with and without sub-well (quantum dots) of InAs (InSb) or inter-band photodetectors to minimize the leakage currents and enables BLIP operation at higher temperatures (>70 K).

The advantages claimed for this invention are:
1) Addition of sub-well in the standard QWIP increases the responsivity.
2) Two colors will allow absolute calibration as compared to single color, which require black body.
3) The concept can apply to n-type or p-type QWIP and any other material system.
4) The structure can be designed to give any two-color response such as: MW-MW, MW-LW, and LW-LW.
5) The concept can be applied to other III-V, IV-IV, and II-VI compound semiconductors.
6) No complex processing and requires only two grating to couple light.
7) Reduced dark currents using barrier in collector minimizes the noise that increases the detectivity.
8) The concept can be applied to inter-band detectors such as InAs/GaInSb by adding InSb sub-well to increase the responsivity and extend the wavelength to very long wavelength infrared (VLWIIR).
9) Two sets of structures can be integrated vertically or by selective epitaxy to give Four-color detector and which uses four grating to couple light.
10) The detectors can be programmable.
11) The barriers and wells (except thin InAs sub-well) are lattice matched to InP substrate.

While the preferred embodiments of the invention have been described, it will be apparent to those skilled in the art that various modifications may be made in the embodiments without departing from the spirit of the present invention. Such modifications are all within the scope of this invention.

1. An integrated dual-wavelength quantum well infrared photodetector (QWIP), comprising:
a common semiconductor substrate;
at least one standard quantum well in said substrate to yield a peak photo response at first wavelength; and
at least one sub-well in said substrate to yield a peak photo response at a second wavelength different from said first wavelength.

2. The photodetector as described in claim 1, wherein said first quantum well and said sub-well are separated by a barrier layer.

3. The photodetector as described in claim 2, wherein said photodetector is structured with a sequence of said barrier-said first quantum well-said sub-well-said barrier.

4. The photodetector as described in claim 3, wherein said sequence is periodic.

5. The photodetector as described in claim 4, wherein said sequence is vertically integrated.

6. The photodetector as described in claim 2, wherein said quantum well is of GaInAs, sub-well is of InAs, said barrier is of AlInAs, and said substrate is of InP.

7. The photodetector as described in claim 1, wherein said first wavelength and said second wavelength are merged to yield a broad-band photoresponse.

8. The photodetector as described in claim 1, wherein said first wavelength and said second wavelength are selected from a pair of the group consisting of near infrared (NIR), mid-wavelength infrared (MW), and long-wavelength infrared (LW).

9. The photodetector as described in claim 1, wherein said two dual wavelength structures are integrated vertically to form the group consisting of MW-MW, LW-LW, MW

10. The photodetector as described in claim 1, wherein said two dual wavelength structures are integrated by using selective epitaxy to form the group consisting of MW-MW, LW-LW

11. The photodetector as described in claim 1, wherein the typical thicknesses of the well are 20-100 Å and the sub-well channel are 5-30 Å

12. The photodetector as described in claim 1, further comprising additional said quantum well and said sub-well to yield a multi-wavelength photodetector.

13. The photodetector as described in claim 1, further comprising a collector of the QWIP and an additional barrier of AlAs (AlSb, and AlAsSb) having large conduction band discontinuity to reduce dark current.

14. The photodetector as described in claim 1, wherein the wells/barriers are selected from the group III-V compound semiconductor family consisting of: GaAs/AlGaAs, GaAs/GaInP, GaAs/AlAs, GaInAs/AlGaAs (AlAs, GaInP), InAsP/AfInAs, InAsP/AlGaAsSb, GaInAs/AlInAs (AlAsSb, AlInAsSb, AlGaAsSb, InP), TlInP(TlGaInP, TlGaInAs)/AlInAs (AlAsSb, AlInAsSb, AlGaAsSb,InP,AlGaPSb), GaAsSb/InP (AlInAs, AlAsSb, AfInAsSb, AlGaAsSb, AlGaPSb), InAs/AlGaAsSb(AlSb, AlAsSb, AlGaSb), GaSb/AlGaAsSb(AlSb, AlAsSb, AlGaSb), InAsSb/AlGaInSb, InSb/AlInSb, GaN/AlGaN(AIN)[,] and GaInN/AlGaN(AIN).

15. The photodetector as described in claim 1, wherein the conduction of the QWIPs is selected from the transport of electrons and holes.

16. The photodetector as described in claim 1, wherein the location of the sub-well in the quantum well is variable, the sub-well can be placed asymmetrically in the layer, and the sub-well can be placed symmetrically in the layer

17. The photodetector as described in claim 1, wherein each said sub-well layer selected from the group consisting of uniformly composition, pseudomorphic composition and self assembled quantum dots,

18. The photodetector as described in claim 1, wherein each said sub-well layer selected from the group consisting of InAs, InSb, TIP, TIAs, TlSb

19. The photodetector as described in claim 1, wherein adding an InSb- subwell in InAs/GaInSb based inter band Strain Layer Superlattice (SLS) detector structures to increase the responsivity and extend the wavelength to very long wavelength infrared (VLWIIR).

20. The photodetector as described in claim 1, wherein any combination of the quantum well/barrier kind pairs deposited on substrate selected from the group consisting of Si, Sapphire. GaN, SiC and AIN are selected from the group III-V compound semiconductor family consisting of GaN/AlGaN, GaInN/AlGaN, GaN/AlN, and GaInN/AIN.

21. The photodetector as described in claim 1, wherein well, barrier and sub-well are selected from the group of IV-IV semiconductor family consisting of Si, Ge, Sn and C

22. The photodetector as described in claim 1, wherein said the quantum well and the barrier are selected from the group of II-VI semiconductors family consisting of ZnSe, ZnS, CdTe, and CdS.

23. The photodetector as described in claim 1, wherein said the well, barrier and the subwell are selected from the group of II-VI/III-V, IV-IV/III-V, WV-IV/I-VI semiconductors family consisting of Si/GaP, Si/ZnS, GaAs/ZnSe, and InSb/CdTe.

24. The photodetector as described in claim 1, wherein said substrate is selected from the group consisting of Si, GaAs, InP, GaN, AIN, SiC and Sapphire

25. The photodetector as described in claim 1, wherein the device is grown via the group consisting of MBE/CBE/MEE/GSMBENVPE/OMVPE/UHVCVD.
